(19) United States
(12) Patent Application Publication
(10) Pub. No.: US 2016/0099173 A1
(43) Pub. Date: Apr. 7, 2016

(54) METHODS FOR ETCHING A BARRIER LAYER FOR AN INTERCONNECTION STRUCTURE FOR SEMICONDUCTOR APPLICATIONS

(71) Applicant: Applied Materials, Inc., Santa Clara, CA (US)

(72) Inventors: Sumit AGARWAL, Dublin, CA (US); Chiu-pien KUO, Zhubei City (TW); Bradley J. HOWARD, Pleasanton, CA (US)

(21) Appl. No.: 14/505,584

(22) Filed: Oct. 3, 2014

(51) Int. Cl. H01L 21/768; H01L 21/3213; H01L 21/02

(52) U.S. Cl. CPC H01L 21/76865; H01L 21/02068; H01L 21/32136; H01L 21/32139

(57) ABSTRACT

Embodiments of the present disclosure provide methods for etching a barrier layer disposed under a metal layer, such as a copper layer, when the metal layer is etched open exposing the barrier layer, to form an interconnection structure in semiconductor devices. In one embodiment, a method of etching a barrier layer disposed under a metal layer formed on a substrate includes supplying a first etching gas mixture comprising a hydrogen containing gas and an inert gas into a processing chamber to clean a surface of a barrier layer disposed on a substrate for a first period of time, supplying a second etching gas mixture comprising fluorine containing gas into the processing chamber to etch the barrier layer, and switching to supply the first etching gas in the processing chamber to clean the etched barrier layer for a second period of time.

### BACKGROUND

1. Field

Embodiments of the present disclosure generally relate to methods of etching a barrier layer, and more particularly to methods of etching a barrier layer disposed under a metal material above a low-k dielectric layer to form interconnection structures in semiconductor applications.

2. Description of the Related Art

Integrated circuits have evolved into complex devices that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components are reduced to the sub-50 nm scale, it is necessary to use low resistivity conductive materials (e.g., copper) as well as low dielectric constant insulating materials (dielectric constant less than about 4) to obtain suitable electrical performance from such components.

The demands for greater integrated circuit densities also impose demands on the process sequences used in the manufacture of integrated circuit components. As the physical dimensions of the structures used to form semiconductor devices are pushed against technology limits, the process of accurate pattern transfer for structures that have small critical dimensions and high aspect ratios has become increasingly difficult. Copper is commonly used to form interconnects a sub-micron device nodes due to its low resistivity compared to aluminum. Copper interconnects are electrically isolated from each other by an insulating material. When the distance between adjacent metal interconnects and/or thickness of the insulating material has sub-micron dimensions, capacitive coupling may potentially occur between such interconnects. Capacitive coupling between adjacent metal interconnects may cause cross talk and/or resistance-capacitance (RC) delay which degrades the overall performance of the integrated circuit. In order to prevent capacitive coupling between adjacent metal interconnects, low dielectric constant (low-k) insulating materials (e.g. dielectric constants less than about 4.0) are needed.

Copper interconnect systems are typically fabricated using a damascene process in which trenches and vias are etched into dielectric layers. The trenches and vias are filled with copper, which is then planarized using, for example, a chemical-mechanical planarization (CMP) process. However, several disadvantages associated with copper damascene structure have become severe concerns as feature sizes continue to decrease. For example, small feature size of the metal lines generally requires higher aspect ratios, which adversely increases the difficulty in filling such features to form void free metal structures. Forming a liner layer within high aspect features is particularly difficult. Furthermore, as feature sizes continue to decrease, the liner layer cannot scale, thus resulting in the liner layer becoming a greater fraction of that particular feature. Additionally, as the feature dimensions become comparable to the bulk mean free path, the effective resistivity of copper features will increase because of non-negligible electron scattering at the copper-barrier interface and at grain boundaries.

Accordingly, an alternate metal patterning using subtractive metal etching process has recently gained wide attention. A dry plasma etching process is performed to pattern the metal materials to form one or more patterns in the interconnect structure using a hardmask layer disposed on the metal materials as a mask. After the metal etching process, a barrier layer disposed underneath the metal layer is then exposed to be etched. A barrier layer is often utilized to separate the metal interconnects from the dielectric bulk insulating materials disposed underneath. The barrier layer minimizes the diffusion of the metal from the interconnect material into the dielectric bulk insulating material. Diffusion of the metal into the dielectric bulk insulating material is undesirable because such diffusion can affect the electrical performance of the integrated circuit, or render the circuit inoperative. The barrier layer serves as an etch-stop layer for metal layer etching process, so that the underlying dielectric will not be exposed to the etching environment. Thus, when etching the barrier layer to expose portion of the underlying metal layer to manufacture the interconnection structures, the similarity of the materials selected for the metal layer, hardmask layer and barrier layer results in similar etch properties, thereby causing poor selectivity during etching. As the barrier layer is etched, the metal layer as well as the hardmask layer disposed on the metal layer may be attacked by the reactive etchant species, resulting in non-uniformity or tapered profile on the top and/or sidewall of the metal layer. In some case, it is desirable to remove the remaining hardmask layer along with the barrier layer with a high selectivity to metal layer so that a tapered profile of the metal layer may be eliminated.

Therefore, there is a need for a method of etching a barrier layer with high selectivity to a metal layer.

### SUMMARY

Embodiments of the present disclosure provide methods for etching a barrier layer disposed under a metal layer, such as a copper layer, when the metal layer is etched open exposing the barrier layer, to form an interconnection structure in semiconductor devices. In one embodiment, a method of etching a barrier layer disposed under a metal layer formed on a substrate includes supplying a first etching gas mixture comprising a hydrogen containing gas and an inert gas into a processing chamber to clean a surface of a barrier layer disposed on a substrate for a first period of time, supplying a second etching gas mixture comprising fluorine containing gas into the processing chamber to etch the barrier layer, and switching to supply the first etching gas in the processing chamber to clean the etched barrier layer for a second period of time.

In another embodiment, a method of etching a barrier layer disposed on a substrate includes performing an etching break-through process to sputter a surface of a barrier layer exposed by a patterned metal layer formed on the substrate, wherein the barrier layer is a Ta containing material or a Ti containing material for a first period of time, performing a main etching process to remove a portion of the barrier layer, the portion of the barrier layer has a thickness about 10 percent to 25 percent of a total thickness of the barrier layer, and performing a cleaning process to clean a surface of the barrier layer from the substrate for a second period of time, wherein the cleaning process comprises a gas mixture substantially the same as a gas mixture supplying in the etching break-through process.

In yet another embodiment, a method of etching a barrier layer disposed on a substrate includes performing an etching break-through process to sputter a surface of a barrier layer exposed by a patterned metal layer formed on the substrate for a first period of time, wherein the barrier layer is a Ta containing material or a Ti containing material for a first period of time, the etching break-through process including first gas mixture including a H₂ gas and a He gas, performing a main etching process to remove a portion of the barrier layer by supplying a second gas mixture including a fluorine gas, and performing a cleaning process to clean a surface of the barrier layer from the substrate for a second period of time, wherein the cleaning process comprises the first gas mixture and the first period of time is at least 3 times longer than the second period of time.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts an apparatus utilized to pattern a barrier layer formed on a substrate to manufacture an interconnection structure;

FIG. 2 depicts a flow diagram of a method for patterning a barrier layer to form features into the barrier layer to manufacture an interconnection structure; and

FIG. 3A-3D depict one embodiment of a sequence for patterning a barrier layer to form features into the barrier layer to manufacture an interconnection structure in accordance with the embodiment depicted in FIG. 2.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this disclosure and are therefore not to be considered limiting of its scope, for the disclosure may admit to other equally effective embodiments.

### DETAILED DESCRIPTION

The present disclosure provides methods for patterning a barrier layer on a substrate to form features in the barrier layer with a high selectivity to the adjacent metal layer and hardmask layer for manufacturing an interconnection structure for semiconductor devices. In one embodiment, the barrier layer etching process is a cyclic etching process to incrementally etch the barrier layer as well as removing etching by-products generated during the etching process without attacking a nearby metal layer, such as a cooper layer. The cyclic etching process includes repeatedly forming a two etching steps including a first stage of a breaking-through process to initially etch a top portion of the barrier layer or a gentle sputter cleaning process to clean surface residuals, and a second stage of a main etching process to incrementally etch the barrier layer without aggressively attaching the nearby metal layer. Finally, after several cycles of the first and the second step etching process, the barrier layer may be removed to expose an underlying structure to form interconnection structures. By utilizing the cyclic barrier etching process, an accurate control of etching selectivity and etching stop point may be obtained to provide a good profile control of the features formed in the barrier layer.

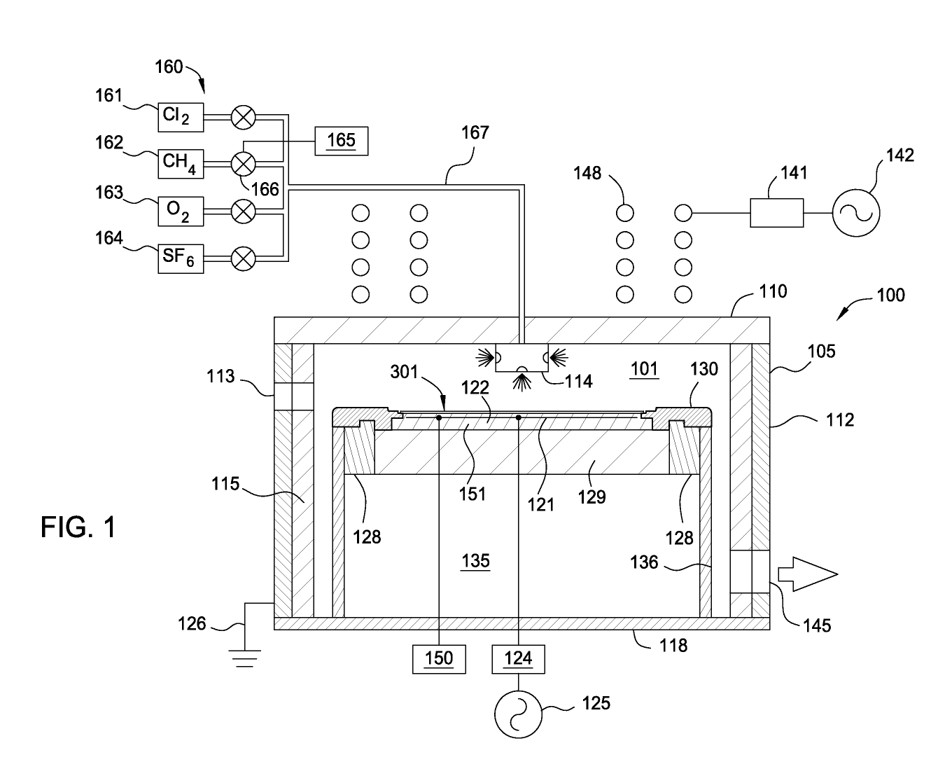

FIG. 1 is a simplified cutaway view for an exemplary etch processing chamber 100 for etching a barrier layer. The exemplary etch processing chamber 100 is suitable for removing one or more film layers from the substrate 301. One example of the process chamber that may be adapted to benefit from the disclosure is an AdvantEdge Mesa Etch processing chamber, available from Applied Materials, Inc., located in Santa Clara, Calif. It is contemplated that other process chambers, including those from other manufactures, may be adapted to practice embodiments of the disclosure.

The etching processing chamber 100 includes a chamber body 105 having a chamber volume 101 defined therein. The chamber body 105 has sidewalls 112 and a bottom 118 which are coupled to ground 126. The sidewalls 112 have a liner 115 to protect the sidewalls 112 and extend the time between maintenance cycles of the etching processing chamber 100. The dimensions of the chamber body 105 and related components of the etching processing chamber 100 are not limited and generally are proportionally larger than the size of the substrate 301 to be processed therein. Examples of substrate sizes include 200 mm diameter, 250 mm diameter, 300 mm diameter and 450 mm diameter, among others.

The chamber body 105 supports a chamber lid assembly 110 to enclose the chamber volume 101. The chamber body 105 may be fabricated from aluminum or other suitable materials. A substrate access port 113 is formed through the sidewall 112 of the chamber body 105, facilitating the transfer of the substrate 301 into and out of the etching processing chamber 100. The access port 113 may be coupled to a transfer chamber and/or other chambers of a substrate processing system (not shown).

A pumping port 145 is formed through the sidewall 112 of the chamber body 105 and connected to the chamber volume 101. A pumping device (not shown) is coupled through the pumping port 145 to the chamber volume 101 to evacuate and control the pressure therein. The pumping device may include one or more pumps and throttle valves.

A gas panel 160 is coupled by a gas line 167 to the chamber body 105 to supply process gases into the chamber volume 101. The gas panel 160 may include one or more process gas sources 161, 162, 163, 164 and may additionally include inert gases, non-reactive gases, and reactive gases, if desired. Examples of process gases that may be provided by the gas panel 160 include, but are not limited to, hydrocarbon containing gas including methane (CH₄), sulfur hexafluoride (SF₆), carbon tetrafluoride (CF₄), hydrogen bromide (HBr), hydrocarbon containing gas, argon gas (Ar), chlorine (O₂), nitrogen (N2), helium (He) and oxygen gas (O₂). Additionally, process gases may include chlorine, fluorine, oxygen and hydrogen containing gases such as BCl₃, C₂F₄, C₄F₈, C₄F₆, CHF₃, CH₂F₂, CH₃F, NF₃, CO₂, SO₂, CO, and H₂ among others.

Valves 166 control the flow of the process gases from the sources 161, 162, 163, 164 from the gas panel 160 and are managed by a controller 165. The flow of the gases supplied to the chamber body 105 from the gas panel 160 may include combinations of the gases.

The lid assembly 110 may include a nozzle 114. The nozzle 114 has one or more ports for introducing the process gases from the sources 161, 162, 164, 163 of the gas panel 160 into the chamber volume 101. After the process gases are introduced into the etch processing chamber 100, the gases are energized to form plasma. An antenna 148, such as one or more inductor coils, may be provided adjacent to the etch processing chamber 100. An antenna power supply 142 may power the antenna 148 through a match circuit 141 to inductively couple energy, such as RF energy, to the process gas to maintain a plasma formed from the process gas in the chamber volume 101 of the etch processing chamber 100. Alternatively, or in addition to the antenna power supply 142, process electrodes below the substrate 301 and/or above the substrate 301 may be used to capacitively couple RF power to the process gases to maintain the plasma within the chamber volume 101. The operation of the power supply 142 may be controlled by a controller, such as controller 165, that also controls the operation of other components in the etching processing chamber 100.

A substrate support pedestal 135 is disposed in the chamber volume 101 to support the substrate 301 during processing. The support pedestal 135 may include an electrostatic chuck 122 for holding the substrate 301 during processing. The electrostatic chuck (ESC) 122 uses the electrostatic attraction to hold the substrate 301 to the substrate support pedestal 135. The ESC 122 is powered by an RF power supply 125 integrated with a match circuit 124. The ESC 122 comprises an electrode 121 embedded within a dielectric body. The electrode 121 is coupled to the RF power supply 125 and provides a bias which attracts plasma ions, formed by the process gases in the chamber volume 101, to the ESC 122 and substrate 301 positioned thereon. The RF power supply 125 may cycle on and off, or pulse, during processing of the substrate 301. The ESC 122 has an isolator 128 for the purpose of making the sidewall of the ESC 122 less attractive to the plasma to prolong the maintenance life cycle of the ESC 122. Additionally, the substrate support pedestal 135 may have a cathode liner 136 to protect the sidewalls of the substrate support pedestal 135 from the plasma gases and to extend the time between maintenance of the etch processing chamber 100.

Furthermore, the electrode 121 is coupled to a power source 150. The power source 150 provides a chucking voltage of about 200 volts to about 2000 volts to the electrode 121. The power source 150 may also include a system controller for controlling the operation of the electrode 121 by directing a DC current to the electrode 121 for chucking and de-chucking the substrate 301.

The ESC 122 may include heaters disposed therein and connected to a power source (not shown), for heating the substrate, while a cooling base 129 supporting the ESC 122 may include conduits for circulating a heat transfer fluid to maintain a temperature of the ESC 122 and substrate 301 disposed thereon. The ESC 122 is configured to perform in the temperature range required by the thermal budget of the device being fabricated on the substrate 301. For example, the ESC 122 may be configured to maintain the substrate 301 at a temperature of about minus about 25 degrees Celsius to about 500 degrees Celsius for certain embodiments.

The cooling base 129 is provided to assist in controlling the temperature of the substrate 301. To mitigate process drift and time, the temperature of the substrate 301 may be maintained substantially constant by the cooling base 129 throughout the time the substrate 301 is in the etch chamber. In one embodiment, the temperature of the substrate 301 is maintained throughout subsequent etch processes at about 70 to 90 degrees Celsius.

A cover ring 130 is disposed on the ESC 122 and along the periphery of the substrate support pedestal 135. The cover ring 130 is configured to confine etching gases to a desired portion of the exposed top surface of the substrate 301, while shielding the top surface of the substrate support pedestal 135 from the plasma environment inside the etch processing chamber 100. Lift pins (not shown) are selectively moved through the substrate support pedestal 135 to lift the substrate 301 above the substrate support pedestal 135 to facilitate access to the substrate 301 by a transfer robot (not shown) or other suitable transfer mechanism.

The controller 165 may be utilized to control the process sequence, regulating the gas flows from the gas panel 160 into the etch processing chamber 100 and other process parameters. Software routines, when executed by the CPU, transform the CPU into a specific purpose computer (controller) that controls the etch processing chamber 100 such that the processes are performed in accordance with the present disclosure. The software routines may also be stored and/or executed by a second controller (not shown) that is collocated with the etch processing chamber 100.

The substrate 301 has various film layers disposed thereon which may include at least one barrier layer and a metal layer disposed on the barrier layer. The various film layers may require etch recipes which are unique for the different compositions of the other film layers in the substrate 301. Multilevel interconnects that lie at the heart of the VLSI and ULSI technology may require the fabrication of high aspect ratio features, such as vias and other interconnects. Constructing the multilevel interconnects may require one or more etch recipes to form patterns in the various film layers. These recipes may be performed in a single etch processing chamber or across several etch processing chambers. Each etch processing chamber may be configured to etch with one or more of the etch recipes. In one embodiment, etch processing chamber 100 is configured to at least etch a barrier layer disposed between metal layers to form an interconnection structure. For processing parameters provided herein, the etch processing chamber 100 is configured to process a 300 mm diameter substrate, i.e., a substrate having a plan area of about 0.0707 m², or a 450 mm diameter substrate. The process parameters, such as flow and power, may generally be scaled proportionally with the change in the chamber volume or substrate plan area.

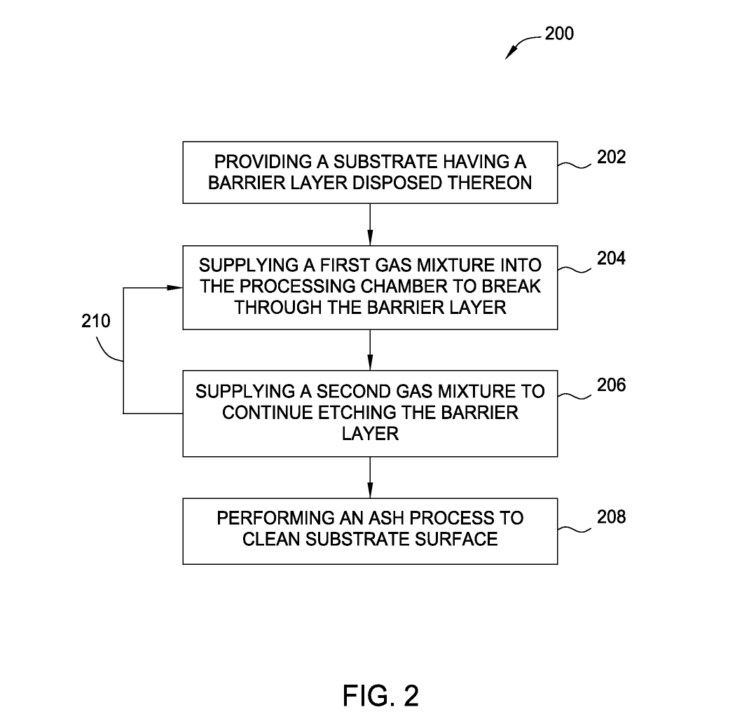

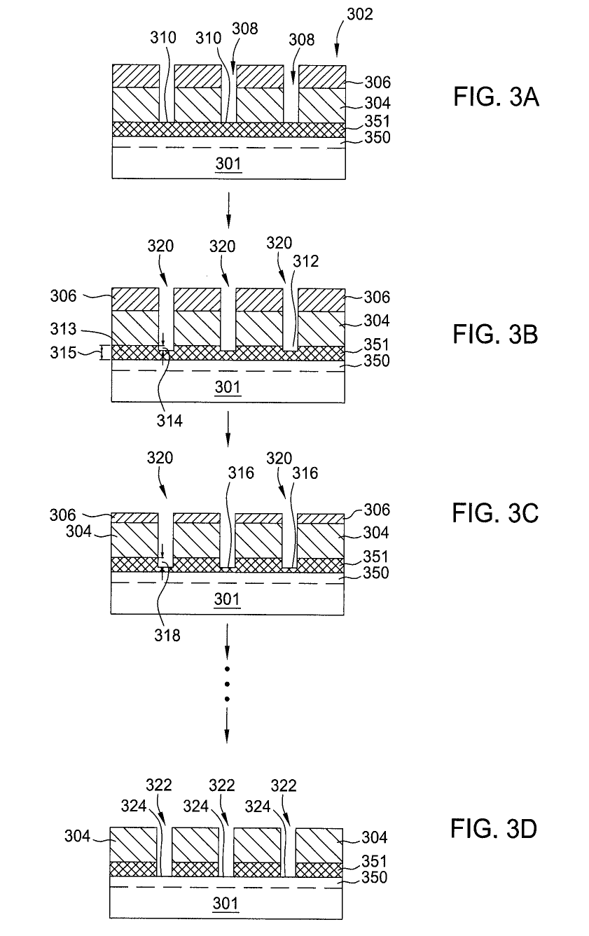

FIG. 2 is a flow diagram of one embodiment of a method 200 for etching a barrier layer disposed under a metal layer, such as a copper layer, or between metal layers for manufacturing an interconnection structure for semiconductor devices. The pattering method 200 may be performed in a processing chamber, such as the processing chamber 100 depicted in FIG. 1, or other suitable processing chamber. FIGS. 3A-3D are schematic cross-sectional views illustrating a sequence for etching a barrier layer disposed under a metal layer or between metal layers disposed on a substrate according to the method 200. Although the method 200 is described below with reference to a substrate having a barrier utilized to form an interconnection structure, the method 200 may also be used to advantage in other transistor device manufacturing applications, among others.

The method 200 begins at block 202 by transferring a substrate, such as the substrate 301, into a processing chamber, such as the processing chamber 100 in FIG. 1. The substrate 301 may be a silicon based material or any suitable insulating materials or conductive materials as needed, having a hardmask layer 306 and a metal layer 304 disposed on a barrier layer 351 formed on the substrate 301 that may be utilized to form an interconnection structure 302, as shown in FIG. 3A.

As shown in the exemplary embodiment depicted in FIG. 3A, the substrate 301 may have a substantially planar surface, an uneven surface, or a substantially planar surface having a structure formed thereon. In one embodiment, the substrate 301 may be a material such as crystalline silicon (e.g., Si<100>or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate 301 may have various dimensions, such as 200 mm, 300 mm, 450 mm or other diameter wafers, as well as, rectangular or square panels. Unless otherwise noted, embodiments and examples described herein are conducted on substrates with a 300 mm diameter. In the embodiment wherein a SOI structure is utilized for the substrate 301, the substrate 301 may include a buried dielectric layer disposed on a silicon crystalline substrate. In the embodiment depicted herein, the substrate 301 may be a crystalline silicon substrate.

In one particular embodiment, the substrate 301 may have a barrier layer 351 disposed between the metal layer 304 and a low-k insulating dielectric material 350, as shown in dotted line in FIG. 3A. The barrier layer 351 may be fabricated from TaN, TiN, AlN, TaSiN, TiSiN, SiN, SiON, SiC, SiNC, SiOC or other suitable materials. Suitable examples of the low-k insulating dielectric material 350 that can be used as the barrier layer 351 includes SiO containing materials, SiN containing materials, SiOC containing materials, SiC containing materials, carbon based materials, or other suitable materials. In one example, the barrier layer 351 described herein is a Ta containing layer or a Ti containing layer, such as TaN, TiN, Ta alloys or Ti alloys. The barrier layer 351 may have a thickness between about 10 Å and about 200 Å, such as between about 15 Å and about 100 Å, for example about 20 Å and about 50 Å.

In one embodiment, the metal layer 304 is disposed on the substrate 301. The metal layer 304 may be fabricated from tungsten (W), tantalum (Ta), titanium (Ti), copper (Cu), ruthenium (Ru), nickel (Ni), cobalt (Co), chromium (Cr), iron (Fe), manganese (Mn), aluminum (Al), hafnium (Hf), vanadium (V), molybdenum (Mo), palladium (Pd), gold (Au), silver (Au), platinum (Pt), alloys thereof, and combinations thereof, among others. In the embodiment depicted in FIGS. 3A-3D, the metal layer 304 is a copper layer or a copper alloy layer having a thickness between about 200 Å and about 500 Å, such as about 350 Å.

The hardmask layer 306 is disposed on the metal layer 304. The hardmask layer 306 and the metal layer 304 may all be patterned/etched to facilitate transferring features into the barrier layer 351. The hardmask layer 306 may be fabricated from Ta containing materials, such as Ta, TaN, TaSiN, Ti containing materials, such as Ti, TiN, TiSiN, aluminum containing materials, such as AlN, AlO₃, AlON, alloys thereof and combinations thereof, among others. In the embodiment depicted in FIGS. 3A-3D, the hardmask layer 306 is a Ta containing material or a Ti containing material having a thickness between about 100 Å and about 400 Å, such as 150 Å and about 300 Å.

In the embodiment depicted in FIG. 3A, the hardmask layer 306 and the metal layer 304 are patterned, forming openings 308 therein to exposure a surface 310 of the barrier layer 351 to form features in the barrier layer 351. The barrier layer 351 is then ready to be patterned/etched to form features exposing a portion of the substrate, for example a metal material in the substrate, to facilitate manufacturing an interconnection structure.

At block 204, a first etching gas mixture is supplied into the processing chamber 100 to perform an etching breakthrough process. The etching breakthrough process reaches the surface 310 of the barrier layer 351 exposed by the patterned metal layer 304, as shown in FIG. 3B, until a predetermined depth 314 of a feature 320 is formed in the barrier layer 351. The patterned metal layer 304 and the hardmask layer 306 serve as an etching mask during the etching process of the barrier layer 351. The first etching gas mixture is continuously supplied to etch the barrier layer 351 until the depth 313 of the feature 320 is formed in the barrier layer 351. In one embodiment, the depth 313 may be between about 5 Å and about 100 Å. Alternately, the depth 313 may be between about 1 percent and about 50 percent, for example between about 10 percent and about 30 percent, such as about 25 percent, of a total thickness 315 of the barrier layer 351.

It is noted that this etching breakthrough process may also be interpreted as a native oxide removal/surface opening process to remove surface native oxide or to remove etching residues left over from previous metal etching processes so as to assist etching the barrier layer 351. Thus, such native oxide removal/surface opening process performed at block 204 provides a gentle surface sputtering effect to remove the native oxide layer formed on the surface 310 of the barrier layer 351, exposing the fresh barrier layer 351 ready to be etched and removed from the surface.

In one embodiment, the first gas mixture including at least one of a hydrogen containing gas and optionally an inert gas is supplied into the processing chamber to remove the native oxide and/or other related surface residuals from the substrate 301. The hydrogen containing gas and/or an inert gas supplied from the first gas mixture may gently sputter clean the native oxides, polymers or residuals remaining on the substrate so as to provide a clean surface to etch the barrier layer 351 with good profile/feature transfer. In one embodiment, the hydrogen containing gas supplied in the ash gas mixture includes H₂ and the inert gas supplied in the first gas mixture includes He, Ar, and the like. In one particular example, the first gas mixture includes a H₂ gas and a He gas.

In one embodiment, for the first cycle of the process including the block 204 and the block 206, the first gas mixture supplied at block 204 may be controlled for a duration long enough to ensure that a fresh surface, e.g., native oxide or surface residuals substantially removed, of the barrier layer 351 is exposed for etching. In one embodiment, the process time for the first cycle for supplying the first gas mixture at block 204 is controlled for a first period of time of between about 100 seconds and about 200 seconds, such as about 150 seconds. After the first gas mixture supplied in the first cycle, a second gas mixture will then be supplied to performing an etching process at block 206, which will be discussed in greater detail below. Subsequently, in a second cycle including the processes of block 204 and block 206, the first gas mixture at block 204 may be supplied a second period of time to mainly flash clean the etching by-product from the substrate surface, so as to facilitate continuation of etching the barrier layer 351 without early block-up of the feature 320 resulting from residual build-up or by-product re-deposit. The second period of time may be a relatively shorter period of time as compared to the first period of time. For example, for the cycles following the first cycle (starting from the second cycle of the process), the first gas mixture supplied at block 204 for the second period of time may be controlled for at between about 10 seconds and about 50 seconds, such as about 30 seconds, rather than the first period of time of between 100 seconds and about 200 seconds in the first cycle. The first period of time for the first cycle of the cleaning process of block 204 is at least about 3 times longer than the second period of time for the subsequent cycle (staring from the second cycle) of the cleaning process of block 204.

In one embodiment, the H₂ gas supplied in the first etching gas mixture may be maintained at a flow rate by volume between about 5 sccm and about 500 sccm, such as about 10 sccm and about 150 sccm. The He gas supplied in the first etching gas mixture may be maintained at a flow rate by volume between about 5 sccm and about 500 sccm, such as about 10 sccm and about 150 sccm. In one example, the H₂ gas and the He gas supplied in the first etching gas mixture may be controlled at a ratio between about 1:3 and about 3:1, such as about 1:1.

After the first etching gas mixture is supplied to the processing chamber mixture, RF source power is supplied to form a plasma from the first etching gas mixture therein. The RF source power may be supplied between about 100 Watts and about 2000 Watts and at a frequency between about 400 kHz and about 13.56 MHz. A RF bias power may also be supplied as needed. The RF bias power may be supplied at less than 200 Watts, between about 30 Watts and about 160 Watts, to reduce bias bombardment impact to the substrate. In one embodiment, the RF source power may be pulsed with a duty cycle between about 10 to about 95 percent at a RF frequency between about 500 Hz and about 10 kHz.

Several process parameters may also be controlled while supplying the etching gas mixture to perform the etching process. The pressure of the processing chamber may be controlled at between about 0.5 milliTorr and about 500 milliTorr, such as between about 4 milliTorr and about 30 milliTorr. A substrate temperature is maintained between about 15 degrees Celsius to about 300 degrees Celsius, such as between about 5 degrees Celsius and about 100 degrees Celsius, for example about 80 degree Celsius. The first etching gas mixture for performing the etching process in the first cycle may be performed for a duration of between about 100 seconds and about 200 seconds, such as about 150 seconds to etch the barrier layer 351 to the depth 313 of between about 1 Å and about 10 Å, or merely cleaning out the surface native oxide or polymer residuals. Alternatively, the etching process may remove between about 1 percent and about 10 percent of the thickness of the barrier layer 351 from the substrate 301

After the breakthrough/native oxide surface cleaning process is performed at block 204, the surface native oxide and/or other related compounds, as well as a portion of the barrier layer 351, if necessary, present on the substrate 301 may be then removed from the substrate 301.

At block 206, a second gas mixture is supplied into the processing chamber 100 to perform a main etching process to etch the portions 312 of the barrier layer 351 exposed by the patterned hardmask layer 306 and the metal layer 304, as shown in FIG. 3C, until a predetermined second depth 318 of the feature 320 is formed in the barrier layer 351. The patterned hardmask layer 306 and the metal layer 304 serve as an etching mask during the main etching process of the barrier layer etching process at block 206. During the main etching process, the hardmask layer 306 may be consumed and may be completely removed after the barrier layer 351 is etched through. The main etching process is also selected to have a high selectivity to the metal layer 304 as well as the hardmask layer 306. The second etching gas mixture is continuously supplied to etch the barrier layer 351 until the depth 318 of the feature 320 formed in the barrier layer 351 is reached. In one embodiment, the depth 318 may be between about 2 Å and about 50 Å, such as about 10 Å. Alternately, the depth 318 may be between about 10 percent and about 40 percent, such as about 25 percent, of the total thickness 315 of the barrier layer 351.

In one embodiment, the second etching gas mixture selected to etch the barrier layer 351 includes at least fluorine containing gas. In one example, the fluorine containing gas is a carbon-fluorine containing gas. The carbon-fluorine containing gas has a formula CₓH_{y}F_{z}, wherein x, y and z are integers ranging from 1 to 8, 0 to 18, and 2 to 16, respectively. Suitable examples of the carbon-fluorine containing gas include FH₃, CF₂H₂, CF₃H, C₂F₂H₄, C₂F₂H₆, OF₄, C₂F₆, and the like. In a particular embodiment, the carbon-fluorine containing gas is CF₄. In some embodiments, the fluorine containing gas is a NF₃ gas. In yet another example, the second gas mixture may include a NF₃ gas and a CF₄ gas.

It is believed that the carbon-fluorine containing gas may efficiently react with metal atoms, such as Ta or Ti elements, from the barrier layer 351, forming by-products in gas phase or in a solid matrix that can be easily removed from the substrate surface. The carbon-fluorine containing gas supplied in the first gas mixture forms an aggressive etchants to remove most of the barrier layer 351 from the substrate 301. The first etching gas mixture is continuously supplied to etch the barrier layer 351 with high selectively to the metal layer 304. Thus, after the main etching process, profiles and feature dimensions of the metal layer 304 may be substantially maintained with minimum damage. The metal elements from the barrier layer 351 selectively react with the aggressive etchants from the plasma without reacting with the metal layer 304, thus leaving etching by-products in a gas phase which is readily pumped out of the processing chamber or in solid matrix which readily falls on the substrate surface or feature sidewalls. When etching by-products are generated, the process may be proceeded back to block 204, as indicated by the loop 210, to do a second cycle of cleaning process at block 204 and etching process at block 206 to incrementally clean and remove the barrier layer 351 without damage to the structures.

In one embodiment, the second gas mixture may be supplied for a duration of about 3 seconds and about 80 seconds, such as about 10 seconds and about 50 seconds, for example about 30 seconds, to etch away about 25 percent of the total thickness of the barrier layer 351, such as about 10 Å, etched away in each cycle at block 206.

While supplying the second etching gas mixture, an inert gas may also be supplied into the etching gas mixture to assist the profile control as needed. Examples of the inert gas supplied in the gas mixture include one or more of Ar, He, Ne, Kr, Xe or the like.

During the main etching process, RF source power is supplied to form a plasma from the first etching gas mixture therein. The RF source power may be supplied between about 100 Watts and about 2000 Watts and at a frequency between about 400 kHz and about 13.56 MHz. A RF bias power may also be supplied as needed. The RF bias power may be supplied at less than 100 Watts, such as between about 10 Watts and about 50 Watts, to reduce bias bombardment impact to the substrate. In one embodiment, the RF source power may be pulsed with a duty cycle between about 10 to about 95 percent at a RF frequency between about 500 Hz and about 10 kHz.

During the main etching process, a process pressure in the main etching process may be regulated between about 4 mTorr to about 50 mTorr, for example, at about 5 mTorr. A substrate temperature is maintained between about 15 degrees Celsius to about 300 degrees Celsius, such as between about 5 degrees Celsius and about 100 degrees Celsius, for example about 80 degree Celsius.

During the main etching process at block 206, etching by-products may adversely accumulate or adhere on surfaces of the patterned barrier layer 351. Thus, as discussed above, a periodic cleaning process may be performed by looping the process back to block 204, as indicated by the loop 210. The restart of the processes at block 204 may switch the second gas mixture back to the first gas mixture to remove the etching by-products so as to maintain cleanliness of the substrate surface for the subsequent cycles of etching process to continue etching the barrier layer 351 with desired and accurate profile transfer and control.

After one or more cycles of repeating blocks 204 and 206, the barrier layer 351 may be incrementally etched and the surface of the substrate may also be constantly cleaned in each cycle, until a surface 324 of the substrate 301 is exposed, as shown in FIG. 3D, with the hardmask layer 306 completed consumed or removed from the substrate 301. In one example, the processes of block 204 and block 206 may be repeatedly performed for at least three times, such as about 4 times, to etch away the barrier layer 351 exposed by the patterned hardmask layer 306 and the metal layer 304 until the underlying substrate 301 is exposed. Each cycle of the process of block 204 and block 206 may etch away a thickness of about 10 Å of the barrier layer 351. The processing time of the cleaning performed in the block 204 may have a duration of about 30 seconds while etching at block 206 may have a duration of about 10 seconds.

At block 208, after the barrier layer 351 is patterned exposing the substrate 301, a final cleaning process, such as an ashing process, may be performed to remove by-products and/or other related residuals from the substrate. During etching of the barrier layer 351 at block 206, by-products or metal complex and/or other related compounds, which are not formed in a gas phase that can be readily pumped out from the processing chamber, may become solid precipitate falling on the substrate surface. Accordingly, a final cleaning process, such as an ashing process may be performed to efficiently and timely remove the by-products and/or other related compounds from the substrate surface prior to removing the substrate 301 from the processing chamber. Alternatively, the final cleaning process may be performed to etch away etching residuals and by-product so as to ensure cleanliness of the substrate surface and to enhance feature profile precision.

In one embodiment, the final cleaning process may be performed using the same gas mixture as utilized in the block 204, such as the first gas mixture, but with a longer processing time, such as greater than 100 seconds. Process parameters are controlled substantially the same as that controlled in the block 204 with the supply of the first gas mixture. Similarly, it is believed that utilizing a gentle treatment process, e.g., a slight sputter process, may assist physically bombarding and sputtering off the polymer residuals or etching by-products from the substrate surface without adversely and aggressively damaging the substrate surface or the structures, such as the patterned metal layer 304.

In one embodiment, the final cleaning gas mixture, e.g., the first gas mixture, including at least one of a hydrogen containing gas and optionally an inert gas into the processing chamber to gently sputter out the by-products and/or other related compounds from the substrate 301. In one embodiment, the hydrogen containing gas supplied in the ash gas mixture includes H₂ or N₂ and the inert gas supplied in the ash gas mixture includes He, Ar, and the like.

During the final cleaning process, RF source power is supplied to form a plasma from the first etching gas mixture. The RF source power may be supplied between about 100 Watts and about 2000 Watts and at a frequency between about 400 kHz and about 13.56 MHz. A RF bias power may also be supplied as needed. The RF bias power may be supplied at less than 200 Watts, between about 30 Watts and about 160 Watts, to provide minimum bias bombardment impact to the substrate. In one embodiment, the RF source power may be pulsed with a duty cycle between about 10 to about 95 percent at a RF frequency between about 500 Hz and about 10 kHz.

Several process parameters may also be controlled while supplying the etching gas mixture to perform the etching process. The pressure of the processing chamber may be controlled at between about 0.5 milliTorr and about 500 milliTorr, such as between about 4 milliTorr and about 30 milliTorr. A substrate temperature is maintained between about 15 degrees Celsius to about 300 degrees Celsius, between about 5 degrees Celsius and about 100 degrees Celsius, for example about 80 degree Celsius.

After the final cleaning/ashing process is performed, the by-products and/or other related compounds presented on the substrate 301 may be then removed from the substrate 301, forming desired features 322 in the barrier layer 351 exposing portions of surfaces 324 of the substrate 301 to form an interconnection structure therebetween.

Thus, methods for etching a barrier layer after a metal layer is etched open to form interconnection structure are provided. The etching process utilizes a cyclic clean/etch to incrementally etch features in a barrier layer while maintaining desired cleanliness on the substrate surface. The cyclic etching process provides a high selectivity between the barrier layer, metal layer and the hardmask layer so as to maintain good feature/profile control while transferring features into the barrier layer. The methods may advantageously provide the etching process with good feature control and etching efficiency with minimum damage to the metal layer and the underlying substrate, thereby improving feature formation with desired dimension and profile formed in both the barrier layer and the adjacent metal layer disposed on a substrate in applications for interconnection structures of semiconductor chips.

While the foregoing is directed to embodiments of the present disclosure, other and further embodiments of the disclosure may be devised without departing from the basic scope thereof, and the scope thereof is determined by the claims that follow.

1. A method of patterning a barrier layer disposed on a substrate, comprising:
(a) supplying a first etching gas mixture comprising a hydrogen containing gas and an inert gas into a processing chamber to clean a surface of a barrier layer disposed on a substrate for a first period of time;
(b) supplying a second etching gas mixture comprising fluorine containing gas into the processing chamber to etch the barrier layer for between about 10% and about 40% for a total thickness of the barrier layer;
(c) switching to supply the first etching gas in the processing chamber to clean the etched barrier layer for a second period of time for between about 1% and about 10% for the total thickness of the barrier layer, wherein the second period of time is longer than the first period of time; and
(d) repeating step (b) and (c) without repeating step (a) until a surface of the substrate is exposed.

2. (canceled)

3. The method of claim 1, wherein the substrate includes a patterned metal layer disposed on the barrier layer, exposing a portion of a surface of the barrier layer for cleaning and etching.

4. The method of claim 1, wherein the first period of time is between about 100 seconds and about 200 seconds.

5. The method of claim 1, wherein the second period of time is between about 10 seconds and about 50 seconds.

6. The method of claim 3, the metal layer is a copper layer.

7. The method of claim 1, wherein the barrier layer is a Ta containing material or a Ti containing material.

8. The method of claim 1, wherein supplying the second etching gas mixture further comprising:
etching the barrier layer to about 25 percent of a the total thickness of the barrier layer.

9. The method of claim 1, further comprising:
maintaining a substrate temperature at about 80 degrees Celsius.

10. The method of claim 1, wherein the fluorine containing gas in the second gas mixture is a carbon-fluorine containing gas selected from a group consisting of CFH₃, CF₂H₂, CF₃H, C₂F₂H₄, C₂F₂H₆, CF₄ and C₂F₆.

11. The method of claim 10, wherein the carbon-fluorine containing gas supplied in the first gas mixture is CF₄.

12. The method of claim 1, wherein the fluorine containing gas supplied in the second gas mixture is NF₃.

13. The method of claim 1, wherein the second gas mixture further comprises an inert gas.

14. The method of claim 13, wherein the inert gas supplied in the second gas mixture includes Ar and He.

15. The method of claim 1, further comprising:
performing a final cleaning process for a third period of time of between about 100 seconds and about 200 seconds.

16. The method of claim 15, wherein the final cleaning process includes supplying the first gas mixture to clean a surface of the substrate after the barrier layer is patterned.

17. A method of patterning a hardmask layer disposed on a metal layer formed on a substrate, comprising:
(a) performing an etching break-through process to sputter a surface of a barrier layer exposed by a patterned metal layer formed on the substrate, wherein the barrier layer is a Ta containing material or a Ti containing material for a first period of time;
(b) performing a main etching process to remove a portion of the barrier layer, the portion of the barrier layer has a thickness about 10 percent to 25 percent of a total thickness of the barrier layer; and
(c) performing a cleaning process to clean a surface of the barrier layer from the substrate for a second period of time, wherein the cleaning process comprises a gas mixture substantially the same as a gas mixture supplying in the etching break-through process, wherein the second period of time is greater than the first period of time; and
(d) repeating step (b) and (c) without repeating step (a) until the barrier layer is etched through exposing a surface of the substrate.

18. The method of claim 17, wherein the gas mixture includes H₂ and He.

19. (canceled)

20. A method of patterning a hardmask layer disposed on a metal layer formed on a substrate, comprising:
(a) performing an etching break-through process to sputter a surface of a barrier layer exposed by a patterned metal layer formed on the substrate for a first period of time, wherein the barrier layer is a Ta containing material or a Ti containing material for a first period of time, the etching break-through process including first gas mixture including a H₂ gas and a He gas;
(b) performing a main etching process to remove about 25% of a total thickness a of the barrier layer by supplying a second gas mixture including a fluorine gas;
(c) performing a cleaning process to clean a surface of the barrier layer from the substrate for a second period of time to etch between about 1% and about 10% of the total thickness of the barrier layer, wherein the cleaning process comprises the first gas mixture and the first period of time is at least 3 times longer than the second period of time; and
(d) repeating step (b) and (c) without repeating step (a) until the barrier layer is etched through exposing a surface of the substrate.
